(19) United States
(12) Patent Application Publication
(10) Pub. No.: US 2026/0302127 A1
(43) Pub. Date: Oct. 1, 2026

(54) SAMPLE CHAMBER HEATING ASSEMBLY

(71) Applicants: FEI COMPANY, Hillsboro, OR (US); Brno University of Technology, Brno (CZ)

(72) Inventors: Libor Novák, Brno (CZ); Jan Lásko, Brno (CZ); Tomáš Musálek, Šenov (CZ); Miroslav Kolibal, Brno (CZ)

(21) Appl. No.: 19/096,595

(22) Filed: Mar. 31, 2025

(51) Int. Cl. H01J 37/24; H01J 37/18; H01J 37/20

(52) U.S. Cl. CPC H01J 37/242; H01J 37/18; H01J 37/20; H01J 2237/006

(57) ABSTRACT

A heating assembly for use in a charged particle beam system. The heating assembly includes a reactor system defining a reactor chamber configured to house a sample and including a reactor heater configured to heat the sample, where the reactor system defines an aperture configured to receive a charged particle beam. The heating system also includes a crucible system that includes a precursor housing defining a precursor volume configured to house a precursor, where the precursor volume is in fluid communication with the reactor chamber, and a heating element configured to heat the precursor.

### BACKGROUND

Charged particle beam systems are used in a variety of applications including the manufacturing, repair, and inspection of miniature devices, such as integrated circuits, magnetic recording heads, and photolithography masks. One type of charged particle beam system may include an electron microscope. Electron microscopes are used as imaging tools by focusing an electron beam of a sufficient size from an electron emitter onto a focused location on a sample and then detecting the signal electrons (or photons) that are emitted from the sample at the focused location to generate a high-resolution image of the sample.

### BRIEF SUMMARY

One aspect of the disclosure provides for a heating assembly for use in a charged particle beam system. The heating assembly includes a reactor system defining a reactor chamber configured to house a sample and including a reactor heater configured to heat the sample, where the reactor system defines an aperture configured to receive a charged particle beam. The heating system also includes a crucible system that includes a precursor housing defining a precursor volume configured to house a precursor, where the precursor volume is in fluid communication with the reactor chamber, and a heating element configured to heat the precursor.

Implementations may include one or more of the following features. The heating assembly further may include a gas reservoir in fluid communication with the reactor chamber and the precursor volume, where the gas reservoir may include an inert gas or a reaction gas. The gas reservoir may include a first pressure, the precursor volume may include a second pressure, and the reactor chamber may include a third pressure. The first pressure may be individually greater than the second pressure and the third pressure. The reactor chamber may include a lid that is movable between a closed position, where the lid is disposed over the reactor chamber, and an open position, where the lid is positioned laterally away from the reactor chamber. The lid may define a gas line and the precursor volume may be in fluid communication with the reactor chamber through the gas line. The crucible system may include a cover disposed over the precursor housing and the cover may be removable to expose the precursor housing. The heating element may include a resistive heating coil.

Another aspect of the disclosure provides for a charged particle beam system including a beam column, and a sample chamber that houses a reactor system defining a reactor chamber and including a reactor heater, where a beam axis is defined from the beam column into the reactor chamber, where the reactor system defines an aperture aligned with the beam axis, and a crucible system including a precursor housing in fluid communication with the reactor chamber and a heating element.

Implementations may include one or more of the following features. The sample chamber may include a first pressure, the reactor chamber may include a second pressure, and the precursor housing may include a third pressure. The third pressure may be greater than, or substantially similar to, the second pressure and the second pressure may be greater than, or substantially similar to, the first pressure. The first pressure may include a vacuum pressure. The gas reservoir may include an inert gas or a reaction gas. The charged particle system may further include a gas reservoir in fluid communication with the reactor chamber and the precursor housing, where the gas reservoir includes an inert gas or a reaction gas. The gas reservoir may include a first pressure, the precursor housing may include a second pressure, and the reactor chamber may include a third pressure. The first pressure may be individually greater than the second pressure and the third pressure. The reactor chamber may include a lid that is movable between a closed position, where the lid is disposed over the reactor chamber, and an open position, where the lid is positioned laterally away from the reactor chamber. The lid may define the aperture. The lid may define a gas line and the precursor housing is in fluid communication with the reactor chamber through the gas line. The crucible system may include a cover disposed over the precursor housing and the cover may be removable to expose the precursor housing. The heating element may include a resistive heating coil.

Yet another aspect of the disclosure provides for a method of using a charged particle beam system. The method includes emitting a charged particle beam through a beam column, and an aperture defined by a reactor chamber of a reactor system, onto a sample housed in the reactor chamber, where the reactor system is positioned in a sample chamber and includes a reactor heater. The method also includes activating the reactor heater to heat the sample and activating a heating element of a crucible system positioned in the sample chamber to heat a precursor housed in a precursor housing of the crucible system such that the precursor emits a precursor gas that flows into the reactor chamber, where the precursor housing is in fluid communication with the reactor chamber.

Implementations may include one or more of the following features. The precursor housing may include a first pressure, and the method further may include releasing a gas from a gas reservoir at a second pressure greater than the first pressure to push the precursor gas into the reactor chamber. The method further may include imaging a reaction between the precursor gas and the sample.

### BRIEF DESCRIPTION OF THE DRAWINGS

A further understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 depicts a simplified cross-sectional view of an example charged particle system, according to an embodiment of the disclosure.

FIG. 2 depicts a simplified cross-sectional view of an example heating assembly positioned in a sample chamber, according to an embodiment of the disclosure.

FIG. 3 depicts a simplified cross-sectional view of an example heating assembly in use, according to an embodiment of the disclosure.

FIG. 4 depicts a flowchart for generating an image according to an embodiment of the disclosure.

FIG. 5 depicts a block diagram of an example computer system usable with systems and methods, according to embodiments of the present disclosure.

### DETAILED DESCRIPTION

Charged particle systems that are used in electron microscopy provide high-resolution imaging by detecting signal electrons (e.g., backscattered electrons, secondary electrons, or the like) produced by the elastic and inelastic scattering of a beam of electrons emitted from an electron emitter that interact with atoms of a sample. In one example, the electrons may be emitted from a cathode electrode that is heated by an electric current. The emitted electrons are attracted to an anode placed downstream of the cathode electrode, thus forming an electron beam directed to, and interacting with, the sample. The current of the signal electrons emitted from the electron beam interacting with the sample are measured by one or more electron detectors. This current can be used to generate a high-resolution image of the sample.

Conventional charged particle systems can include a reactor system in the sample chamber that contains a reactor heater and a reactor chamber that houses a sample. A reaction gas (e.g., pure oxygen, pure hydrogen, hydrogen sulfide, hydrogen telluride, hydrogen selenide, or the like) may be introduced in the reactor chamber from a reaction gas reservoir housed outside of the sample chamber while the reactor heater heats the sample. In this manner, the sample may be imaged as the reaction gas reacts with the sample at a certain temperature, which can bring valuable information about the ongoing chemical reaction. The small size of the reactor chamber compared to the sample chamber offers additional benefits. For example, the reactor chamber can minimize oxidation of the sample as it is easier to remove water from the smaller reactor chamber compared to the larger sample chamber. Additionally, the amount of reaction gas required to react with the sample only has to fill the smaller volume of the reactor chamber rather than the entirety of the larger sample chamber.

However, the way these types of reaction gases are provided to the reactor system may be a limiting factor in the availability and types of reactions capable of being imaged. For example, certain reaction gases can be so volatile, and can require such particular care in storing and handling the reaction gas reservoirs to minimize the risks of unsafe interactions with the reaction gas (e.g., careful and specific handling instructions, additional equipment, such as pumps, or the like), that very few (or even no) laboratories may be equipped to handle those reaction gases. Additionally, these types of reaction gases can be costly, especially given the large amount of reaction gas that is typically available for purchase and the small amount of the reaction gas used while imaging the sample. Further, using these reaction gases can be practically infeasible due to the reaction gas potentially reacting with parts of the charged particle system, as well as certain reactions requiring chemicals that are not stored in gaseous form. As such, it may be beneficial to provide an improved method of providing reaction gas to the reactor system.

The present disclosure addresses these issues by providing a charged particle system having a heating assembly that can heat up a solid or liquid precursor (e.g., through vaporization, sublimation, evaporation, or the like), and generate a precursor gas (e.g., a vapor) to flow into the reactor chamber. This precursor gas reacts with the sample while being safer to handle and cheaper to purchase than reservoirs of reaction gas. The precursor gas can provide a similar reactive effect on the sample as the reaction gas. Additionally, heating the precursor may emit a precursor gas that is not typically stored in a gas reservoir, thus allow for the imaging of reactions that are not available using reaction gases as in conventional systems. Accordingly, the heating assembly can reduce the costs and risks associated with imaging certain reactions of the sample while also expanding the possible reactions that can be imaged.

Although the remaining portions of the description will routinely reference scanning electron microscopes (SEM), it will be readily understood by the skilled artisan that the technology is not so limited. The present designs may be employed with other types of charged particle microscope, such as transmission electron microscope (TEM), scanning transmission electron microscope (STEM), dual beam systems including an ion beam source and an electron beam source, reflection electron microscopes (REM), circuit editing microscopes, or the like. Accordingly, the disclosure and claims are not to be considered limited to any particular example microscope discussed, but can be utilized broadly with any number of electron microscopes that may exhibit some or all of the electrical or chemical characteristics of the discussed examples.

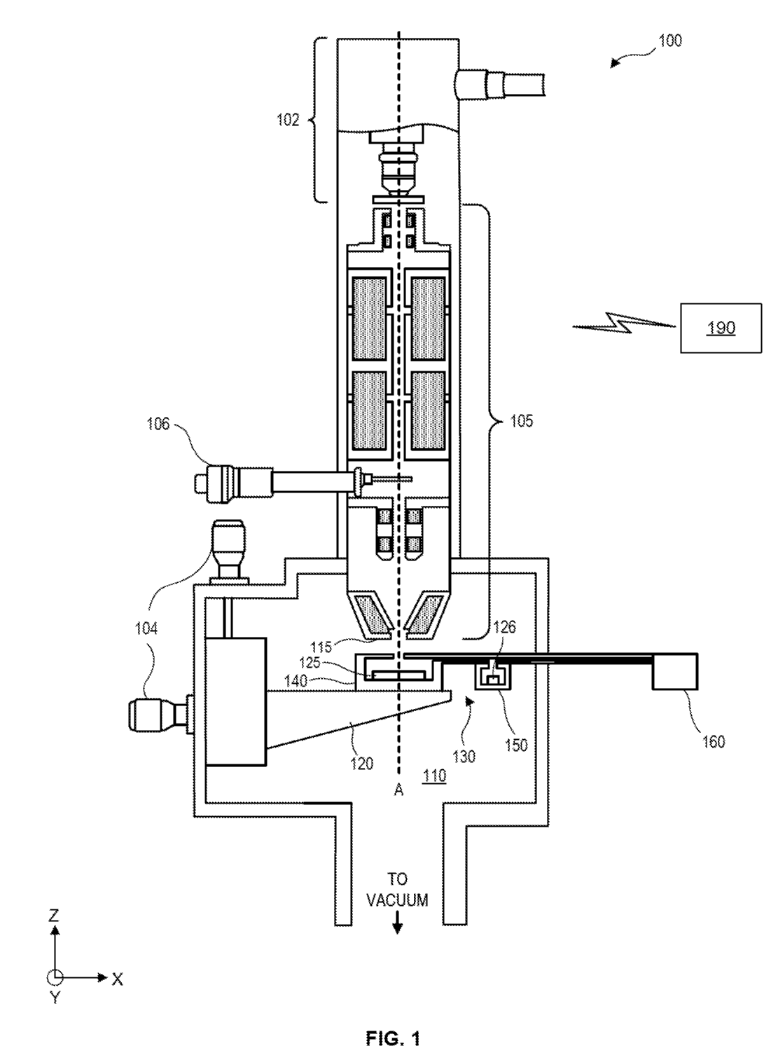

FIG. 1 is a schematic diagram of an example charged particle system 100, in accordance with some embodiments of the present disclosure. Example charged particle system 100 includes multiple sections including an electron source 102, a beam column 105, and a sample chamber 110. The charged particle system 100 may be in electronic communication with a computer system 190 such that electronic information may be exchanged between the charged particle system 100 and the computer system 190 (e.g., data, measurements, instructions, or the like). The electron source 102 includes high-voltage supply components, vacuum system components, and an electron emitter configured to generate a beam of electrons that is accelerated into the beam column 105. The beam column 105, in turn, can include electromagnetic lens elements and/or an aperture plate 106 that are configured to shape and form the beam of electrons from the electron source 102 into a substantially circular beam with a substantially uniform profile transverse to a beam axis A, and that conditions the beam to be focused onto a sample 125 by an objective lens 115.

The beam of electrons is typically characterized by a beam current and an accelerating voltage applied to generate the beam, among other criteria. The ranges of beam current and accelerating voltage can vary between instruments and are typically selected based on material properties of the sample or the type of analysis being conducted. Generally, however, beams of electrons are characterized by an energy from about 0.1 keV (e.g., for an accelerating voltage of 0.1 kV) to about 50 keV and a beam current from picoamperes to microamperes.

The sample chamber 110 and/or the beam column 105 can include multiple detectors for various signals, including but not limited to signal electrons generated by interaction of the beam of electrons and the sample, X-ray photons (e.g., EDAX), other photons (e.g., visible and/or IR cameras), and/or molecular species (e.g., TOF-SIMS where the charged particle system 100 includes an ion beam source, such as in a dual beam system). The sample chamber 110 can also include a multi-axis translation/rotation control system 104 to reposition the sample 125 relative to the beam axis. For example, the control system 104 may control a position of a structure that the sample 125 is housed in, such as a reactor system 140, as discussed below.

The charged particle system 100 may include a heating assembly 130 housed in the sample chamber 110. The heating assembly 130 may include a reactor system 140, a crucible system 150, and a gas reservoir 160 in fluid communication with the reactor system 140 and crucible system 150. The reactor system 140 may house the sample 125 and the crucible system 150 may house a precursor 126. The precursor 126 may be a solid or liquid form of a reaction chemical, such as a single chemical substance or a combination of multiple chemical substances (e.g., a chemical compound). The crucible system 150 may heat up the precursor 126 such that the precursor 126 emits a precursor gas (e.g., through sublimation, vaporization, evaporation, or the like). The gas reservoir 160 may house an inert gas (e.g., nitrogen, argon, or the like) or reaction gas (e.g., oxygen, hydrogen, carbon monoxide, carbon dioxide, or the like). The gas reservoir 160 may release inert gas at a pressure that is higher than the pressure in the crucible system 150 and the pressure in the reactor system 140 such that the inert gas may act as a carrier gas that pushes the precursor gas from the crucible system 150 into the reactor system 140. In this manner, the precursor gas from the precursor 126 may react with the sample 125 housed in the reactor system 140. Although the heating assembly 130 is depicted including only a single crucible system 150 fluidly coupled to the reactor system 140, in other embodiments, there may be more than one crucible system, such as multiple crucible systems for multiple chemicals. As will be described further below, the reactor system 140 can include an aperture permitting transmission of electrons or other charged particles onto the sample 125

As discussed above, conventional charged particle systems can include a reactor system housed in a sample chamber that heats up a sample while introducing a reaction gas in the reactor system from a reaction gas reservoir outside of the sample chamber to image the reaction between the sample and the reaction gas. However, these types of reaction gases may be a limiting factor in the availability and types of reactions capable of being imaged due to the reaction gas’s volatility, cost, risk of undesired reaction with parts of the charged particle system, and availability in certain forms.

The heating assembly 130 may address these issues by using a precursor 126 that is less volatile and more cost effective than a reaction gas used in conventional charged particle systems. For example, the precursor 126 may be a solid or liquid form of reaction chemicals used to react with the sample 125. The solid or liquid form of these reaction chemicals may be much safer and cheaper to use than the gaseous forms of these reaction chemicals. In one example, in conventional charged particle systems, in order to image the reaction between sulfur and the sample, a reservoir of hydrogen sulfide may feed hydrogen sulfide gas into the sample chamber to interact with the sample. However, hydrogen sulfide is highly flammable and toxic, as well as being very expensive. The charged particle system 100, on the other hand, allows for the sample 125 to be imaged reacting to sulfur by using a precursor 126 that is solid sulfur. Solid sulfur is much safer and cheaper than hydrogen sulfide gas. At the same time, solid sulfur can provide a similar gas to react with the sample 125 as hydrogen sulfide because, once the solid sulfur precursor 126 is heated in the crucible system 150 to a sufficient temperature, the solid sulfur precursor 126 may emit gaseous sulfur into the reactor system 140 to react with the sample 125. In this manner, the heating assembly 130 may allow for the sample 125 to be imaged reacting to certain reaction chemicals (e.g., sulfur) while decreasing the risk and minimizing the cost that would typically be required to image the sample 125 reacting to those reaction chemicals using reaction gas reservoirs in a conventional charged particle system.

The sample holder 120 can be operably coupled with the heating assembly 130 such that the sample 125 can be repositioned relative to the beam axis A, as an approach to surveying and/or imaging the sample 125. In this way, one or more charged particle sensors of the present disclosure (e.g., electron detectors) can be disposed in the sample chamber 110 and/or in the beam column 105 and configured to detect signal electrons emanating from the sample.

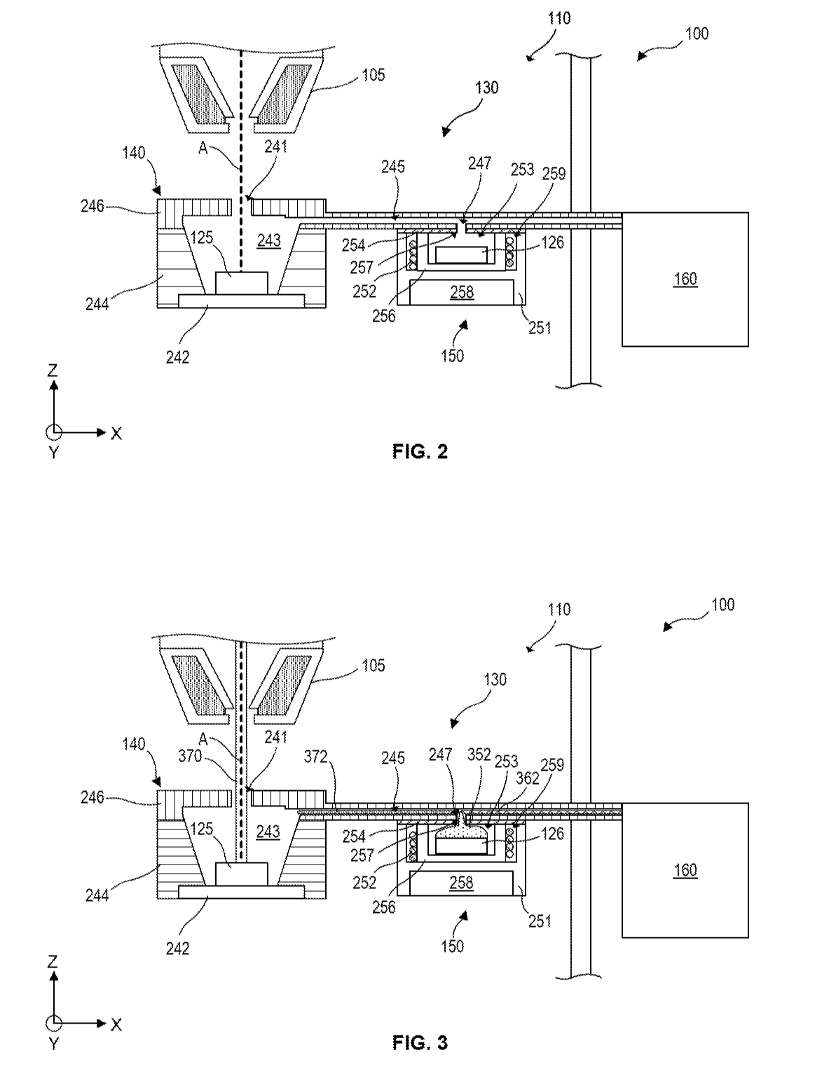

FIG. 2 depicts a partial view of the charged particle system 100 illustrating a more detailed view of the heating assembly 130 than in FIG. 1. It is understood that features ending in like reference numerals as features discussed above are similar, except as noted below. In particular, FIG. 2 depicts the heating assembly 130 before the precursor 126 is heated up.

The reactor system 140 may include a lid 246 coupled to a reactor chamber 244 defining a reactor volume 243 therebetween. The reactor volume 243 may house the sample 125. The lid 246 may define a gas line 245 extending from the reactor volume 243 to the gas reservoir 160 such that the gas reservoir 160 may be in fluid communication with the sample 125. The lid 246 may define a precursor inlet 247 in fluid communication with the crucible system 150 (e.g., with the precursor outlet 257 and precursor volume 253 of the crucible system 150) that allows for a precursor gas (e.g., the precursor gas 352, as shown in FIG. 3) to enter the gas line 245. The lid 246 may also define a beam aperture 241 to allow for a charged particle beam (e.g., the charged particle beam 370, shown in FIG. 3) to flow along the beam axis A from the beam column 105 into the reactor volume 243 through the beam aperture 241 and onto the sample 125. In this manner, the sample 125 may be imaged by the charged particle beam. In some embodiments, the lid 246 may be removable from the reactor chamber 244 from a closed position, where the lid 246 is disposed over the reactor chamber 244, as shown in FIG. 2, and in a closed position, where the lid 246 is positioned laterally away from the reactor chamber 244 (e.g., to change out the sample 125, to clean the lid 246 and/or the reactor chamber 244, or the like). However, in other embodiments, the lid 246 may not be removable from the reactor chamber 244 (e.g., the lid and the reactor chamber being a monolithic structure).

The reactor system 140 may include a reactor heater 242 coupled to the reactor chamber 244. The reactor heater 242 may act as a platform for the sample 125 to be positioned on. In this manner, the reactor heater 242 may more directly provide heat to the sample 125. In other embodiments, there may be one or more components positioned between the sample 125 and the reactor heater 242. The reactor heater 242 may include one or more heating elements that provide heating (e.g., conduction, radiation, convection, or the like) to the sample 125. For example, the reactor heater 242 may be , or include, a miniature resistive heater. The reactor heater 242 may provide heat at temperatures of between about 20 °C and 1400 °C, such as between about 120 °C and 1300 °C, such as between about 220 °C and 1200 °C, such as between about 320 °C and 1100 °C, such as between about 420 °C and 1000 °C, such as between about 520 °C and 900 °C, or the like.

The reactor heater 242 may include a temperature change speed of between about 0.01 K/s and 100,000 K/s, such as between about 0.11 K/s and 10,000 K/s, such as between about 1 K/s and 1,000 K/s, or between about 10 K/s and 100 K/s. As such, the ramping time for a reactor heater 242 to achieve a desired temperature may change corresponding to the temperature change speed (e.g., a lower ramping time with a higher temperature change speed, and vice versa). For example, the ramping time required for the reactor heater 242 to increase from 20 °C to 1020 °C may be 10 ms where the reactor heater 242 includes a temperature change speed of 100,000 K/s. In another example, the ramping time required for the reactor heater 242 to increase from 20 °C to 1020 °C may be 28 hours where the reactor heater 242 includes a temperature change speed of 0.01 K/s. Accordingly, a gas (e.g., a precursor gas) may flow from the gas line 245 into the reactor volume 243 to react with the sample 125 as the reactor heater 242 heats up the sample 125.

The reactor heater 242 may include one or more sensors that can provide various measurements of the reactor volume 243 to the computer system 190. For example, the reactor heater 242 can include a pressure sensor to measure the pressure of the reactor volume 243 and/or a temperature sensor to measure the temperature of the reactor heater 242/sample 125. In some embodiments, the reactor heater may not include all these sensors and, instead, one or more of these sensors may be positioned in the lid and/or the reactor chamber. The reactor heater 242 may have additional sensors, such as a humidity sensor, imaging sensor, charged particles detector, or the like.

The crucible system 150 may include an outer housing 251 and cover 254 defining an outer volume 259 therebetween. The outer housing 251 can house a precursor housing 256 in the outer volume 259. The precursor housing and cover 254 can define a precursor volume 253 therebetween. The housings 251, 256 may include a cylindrical shape, a cubed shape, or other shapes capable of corresponding defining the volumes 253, 259. The precursor volume 253 may house the precursor 126. The cover 254 may define a precursor outlet 257 in fluid communication with the gas line 245 through the precursor inlet 247. In this manner, precursor gas (e.g., the precursor gas 352, as shown in FIG. 3) may flow from the precursor volume 253 when the precursor 126 is heated through the precursor outlet 257 and precursor inlet 247, and into the gas line 245 to flow into the reactor volume 243.

The crucible system 150 may include a heating element 252 positioned in the outer volume 259 and coupled to an exterior of the precursor housing 256 to provide heat (e.g., through conduction, convection, radiation, or the like) to the precursor 126. This may be beneficial to concentrate heat into the precursor volume 253 of the precursor housing 256 rather than heating up other portions of the charged particle system 100 outside of the outer housing 251, which can cause components to shift due to thermal expansion. For example, the heating element 252 can include a resistive heating coil wrapped around the precursor housing 256 to heat the precursor housing 256 and provide conductive heating to the precursor 126. In this example, the resistive heating coil may be a heating wire, such as a tungsten wire (e.g., insulated electrically by an alumina ceramic). However, in other embodiments, the heating element can include a laser heater (e.g., positioned in the precursor volume) that provides radiation heating to the precursor. The heating element 252 can provide a temperature of between about 20 °C and 2300 °C, such as between about 100 °C and 2150 °C, such as between about 200 °C and 2000 °C, such as between about 300 °C and 1850 °C, such as between about 400 °C and 1600 °C, such as between about 500 °C and 1450 °C, such as between about 600 °C and 1300 °C, such as between about 700 °C and 1150 °C, between about 800 °C and 1000 °C, or about 900 °C.

The precursor housing 256 may include material that is chemically inert to most elements and chemical compounds, and is resistant to thermal shock. In this manner, the precursor housing 256 may house the precursor 126 with minimal or no chemical reaction between the precursor 126 and the precursor housing 256. At the same time, the precursor housing 256 may be able to transfer heat from the heating element 252 to the precursor 126 without being damaged by the high temperatures of the heating element 252. For example, the precursor housing 256 may include a ceramic material, such as alumina, quartz, or the like.

The outer housing 251 can be made of a material that shields the components of the charged particle system 100 exterior of the outer housing 251 from light and heat within the outer volume 259. In this manner, reactions that occur within the outer volume 259 may not affect the imaging or performance of other components of the charged particle system 100 outside of the outer volume 259. For example, heating up these other components outside of the outer housing 251 can cause those other components to emit light, which can appear as noise to the images generated using charged particle detectors since charged particle detectors can be sensitive to photons. The outer housing 251 can mitigate heat from affecting these components outside of the outer housing 251 and decrease the risk those components emit light.

The precursor housing 256 may include one or more sensors that can provide various measurements of the precursor volume 253 to the computer system 190. For example, the precursor housing 256 can include one or more of a pressure sensor to measure the pressure of the precursor volume 253 or temperature of the heating element 252/precursor 126. In further embodiments, the precursor housing 256 may have additional sensors, such as humidity sensors, imaging sensors (e.g., a camera or the like), or the like. In some embodiments, the precursor housing may not include all these sensors and, instead, one or more of these sensors may be positioned in the cover and/or the heating element. In yet other embodiments, the outer housing may additionally or alternatively include similar sensors.

The cover 254 may be removably coupled to the lid 246 such that the crucible system 150 may be coupled or decoupled to the lid 246 as desired. This may be beneficial as the crucible system 150 may be designed specifically for the specific element or compound of the precursor 126. For example, the material and design of the crucible system 150 may be particular to the particular chemical element or compound of the precursor 126. In this manner, when a precursor gas is desired that is different from the precursor gas generated from the precursor 126, the crucible system 150 may be decoupled from the lid and a different crucible system designed specifically to provide that different precursor gas may be coupled to the lid instead. However, in other embodiments, the lid, the precursor housing, and/or the outer housing of the crucible system may not be removable from the lid and, instead, may be permanently coupled (e.g., coupled to the lid in a manner that cannot be decoupled without damaging the lid and/or cover), such as through welding, soldering, brazening, or the like. In yet other embodiments, the lid, cover, the precursor housing, and/or the outer housing may be a monolithic structure.

The cover 254 may be removable from the precursor housing 256 to allow for the cover 254 to be replaced, to clean the precursor volume 253, and/or to replace the precursor 126 with another precursor. In particular, after the precursor 126 is heated up to emit a precursor gas (e.g., the precursor gas 352, as shown in FIG. 3), the precursor gas may condense and/or deposit material on the cover 254 as the precursor gas flows out of the precursor volume 253 and into the gas line 245. As such, replacing the cover 254 or cleaning this material build-up on the cover 254 from the precursor gas may be particularly beneficial. However, in other embodiments, the cover and the precursor housing may not be removable from each other, and, instead, may be permanently coupled to each other or a monolithic structure.

The crucible system 150 may include a cooling system 258 forming a part of the outer housing 251 (e.g., a base of the outer housing 251). However, in other embodiments, the cooling system can be a separate component positioned along an exterior surface of the outer housing, within the outer volume of the outer housing, or the like. The cooling system 258 may cool down the precursor housing 256 during, and/or after, the precursor 126 is finished being heated up (e.g., after the sample 125 is imaged). The cooling system 258 may mitigate the risk that the precursor 126 is heated up too much by cooling the precursor housing 256 if the temperature of the precursor volume 253 and/or the precursor 126 becomes too high. The cooling system 258 may include a water-based cooling system, such as a water circulation system. However, in other embodiments, the cooling system may additionally or alternatively include one or more of an air cooling system, Peltier cooling, heat pipe, water cooling, or the like.

As the portion of the lid 246 between the reactor volume 243 and the precursor volume 253 may be colder than the temperature used to heat up the precursor 126 to emit the precursor gas (e.g., the precursor gas 352, as shown in FIG. 3), there may be a risk that the precursor gas cools down and condenses as the precursor gas travels in the portion of the gas line 245 between the reactor volume 243 and the precursor volume 253. Accordingly, it may be beneficial to position the crucible system 150 close to the reactor system 140 to minimize the risk of precursor gas loss as the precursor gas travels from the crucible system 150 to the reactor system 140. For example, the crucible system 150 may be positioned in the sample chamber 110 with the reactor system 140. In some embodiments, the portion of the lid between the reactor volume and the precursor volume may be heated by one or more heating elements to further minimize the risk of precursor gas loss. In this example, heating up the portion of the lid between the reactor volume and the precursor volume may sufficiently decrease the risk of precursor gas loss such that the crucible system may be positioned outside of the sample chamber.

One or more of the sample chamber 110, reactor volume 243, precursor volume 253, or the gas reservoir 160 may include different pressures to allow for gas to flow from the gas reservoir 160 and precursor volume 253 into the reactor volume 243. For example, the sample chamber 110 may be pumped to vacuum pressures by a vacuum pump (not shown). Vacuum pressures may include pressures of less than about 50 mPa, such as less than 30 mPa, such as less than 10 mPa, such as less than 1 mPa, such as less than 0.1 mPa, such as less than about 0.01 mPa, or the like. The reactor volume 243 and the precursor volume 253 may include a substantially similar pressure (e.g., the pressure of each of the volumes 243, 253 may be within about a 20% deviation of each other, such as about a 10% deviation, such as about a 5% deviation, or being completely the same) that is higher than the pressure of the sample chamber 110. The volumes 243, 253 may include a pressure of between about 10 Pa and 10,000 Pa, such as between about 30 Pa, and 900 Pa, such as between about 50 Pa and 800 Pa, such as between about 70 Pa and 700 Pa, such as between about 90 Pa and 600 Pa, such as between about 110 Pa and 500 Pa, such as between about 130 Pa and 400 Pa, such as between about 150 Pa and 300 Pa, such as between about 170 Pa and 200 Pa, or the like. The differences in pressure between the sample chamber 110 and the volumes 243, 253 may allow for gas to flow from the volumes 243, 253 toward the sample chamber 110 through the beam aperture 241 (e.g., for gas to flow from the precursor volume 253 to the reactor volume 243). In other embodiments, the reactor volume may be separately pumped (e.g., through a separate pump coupled to the reactor chamber) to have a lower pressure than the precursor volume but higher than the vacuum pressure of the sample chamber. In yet other embodiments, one or more of the reactor volume, precursor volume, or sample chamber may include a substantially similar pressure.

In some embodiments, the pressures of the volumes 243, 253 may correspond with the pressure that the carrier gas is released from the gas reservoir 160. For example, the pressure of the carrier gas flow may increase the pressure of the volumes 243, 253 as the carrier gas may flow into, and through, the volumes 243, 253. The carrier gas may be released from the gas reservoir 160 at a pressure of between about 1 bar and 70 bar, such as between about 5 bar and 60 bar, such as between about 15 bar and 50 bar, such as between about 25 bar and 40 bar, or about 35 bar. This may be particularly beneficial to reduce the difference in pressure between the vacuum pressure of the sample chamber 110 and the pressures of the volumes 243, 253 required to efficiently flow the precursor gas from the precursor volume 253 into the reactor volume 243. In this manner, the carrier gas may help push the precursor gas entering the gas line 245 into the reactor volume 243 and maximize the amount of precursor gas that interacts with the sample 125. However, in other embodiments, there may be no gas reservoir. Instead, the precursor gas may flow into the reactor system only through the pressure differential between crucible system and the reactor system/sample chamber.

The precursor 126 may be heated up to release a precursor gas in measured doses. For example, the precursor 126 may be divided into multiple dosed portions that, when heated up, emits a known quantity of precursor gas. In this example, the precursor 126 may be separated portions or as a single piece with divisions corresponding with a known quantity of precursor gas once that portion of the precursor 126 is heated up. In some embodiments, the crucible system 150 may include a temperature sensor that measures a temperature gradient along the precursor 126 such that the temperature sensor can measure a temperature of each of the dosed portions of the precursor 126. The heating element 252 may increase in heat to heat up each of the dosed portions of the precursor 126 until the desired dosed portion reaches a certain temperature to emit precursor gas. In this manner, the precursor 126 may be provided in measured doses by adjusting the heating element 252 to heat up the desired dosed portion based on the temperature gradient of the precursor 126 measured by the temperature sensor. The computer system 190 may determine that the particular dose of precursor 126 is finished once the computer system 190 determines that the precursor volume 253 is not receiving any more precursor gas. In some embodiments, more than one dosed portion can be heated up at once.

In another example of providing the precursor gas in measured doses, the precursor housing 256 may include a mass sensor that detects a change in mass of the precursor 126 as the precursor 126 evaporates. For example, the mass sensor may include a quartz crystal microbalance. In this manner, the precursor 126 may be provided in measured doses by adjusting the heating element 252 to heat up each dosed portion based on the measured change of mass of the precursor 126 detected by the mass sensor.

The precursor 126 may include a solid or liquid form of reaction chemicals that would normally be toxic and/or expensive if used in gaseous form to react with the sample 125. For example, the precursor 126 may include a solid or liquid form of telluride, selenide, or the like. In other examples, the precursor 126 may be a solid or liquid form of reaction chemicals that do not stably exist in gaseous form and, instead, may be provided only by heating up a solid or liquid precursor 126, such as certain metal complexes (e.g., metal acetylacetonates, metallocenes, phthalocyanines, or the like). Other examples of the precursor 126 may be a solid or liquid form of reaction chemicals used in an imaging process to image transition metal dichalcogenides, such as: tungsten ditelluride and molybdenum ditelluride for topological insulators and device fabrication; rhenium diselenide and rhenium disulfide for ultrasensitive light sensors and optoelectronic memory devices ; tungsten disulfide and molybdenum disulfide for gas detectors, electronic materials, and battery materials; and tantalum diselenide, tantalum disulfide, niobium disulfide, niobium diselenide, niobium ditelluride, titanium ditelluride, titanium diselenide, titanium disulfide, vanadium ditelluride, and vanadium diselenide for electronic materials, energy storage, low temperature superconductors. In yet other examples of the precursor 126 may be a solid or liquid form of reaction chemicals used to image nanowire growing using a vapor-liquid-solid process, such as gallium arsenide, zinc selenide, zinc telluride, cadmium selenide, cadmium sulfide, zinc sulfide for electronics, and inorganic halide perovskites (e.g., CsXH3, where X is metal (Pb, Sn) and H is halide (Br, Cl, F) for optoelectronics. In yet other examples, the precursor 126 may include solid or liquid forms of reaction chemicals that, in gaseous form, may react with certain parts of the charged particle system 100 or a pumping system coupled to the charged particle system 100. For example, this may include chlorides that affect the rubber used in vacuum sealing, fluorides that can degrade silicon-based components (e.g., the charged particle detectors), or hydrogen disulfide that may cause embrittlement of metal components (e.g., the turbomolecular pump).

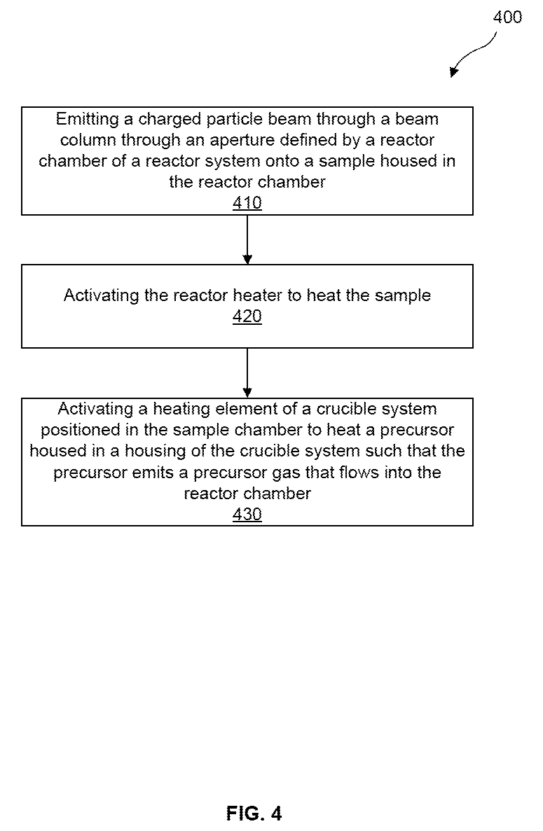

FIG. 3 depicts the heating assembly 130 in use. FIG. 4 depicts an example flowchart showing a process 400 for generating an image. Unless specified otherwise, the flowchart in FIG. 4 will be described with reference to the charged particle system 100 shown in FIG. 3. At least some of the below operation of the components of the charged particle system 100 can be performed under the control of or by the computer system 190. It is understood that features ending in like reference numerals as features discussed above are similar, except as noted below.

Block 410 may include emitting a charged particle beam 370 through a beam column 105 through an aperture 241 defined by a reactor chamber 244 of a reactor system 140 onto a sample 125 housed in the reactor chamber 244. The reactor system 140 is positioned in the sample chamber 110 and includes a reactor heater 242. The beam column 105 may begin emitting the charged particle beam 370 onto the sample 125 prior to any precursor gas 352 reacts with the sample 125. However, in other embodiments, the beam column may begin emitting the charged particle beam onto the sample after the precursor gas is reacting with the sample.

Block 420 may include activating the reactor heater 242 to heat the sample 125. The reactor heater 242 may begin heating the sample 125 prior to any precursor gas 352 reacting with the sample 125. However, in other embodiments, the reactor heater may begin heating the sample after the precursor gas is reacting with the sample.

Block 430 may include activating a heating element 252 of a crucible system 150 positioned in the sample chamber 110 to heat a precursor 126 housed in a precursor housing 256 of the crucible system 150 such that the precursor 126 emits a precursor gas 352 that flows into the reactor chamber 244. The precursor housing 256 may be in fluid communication with the reactor chamber 242. In particular, the heating element 252 may heat the precursor 126 to a temperature sufficient for the precursor 126 to emit precursor gas 352 based on the material of the precursor 126. The precursor gas 352 may begin flowing out of the precursor volume 253 into the gas line 245 toward the beam aperture 241 based on a pressure differential between the precursor volume 253 and the sample chamber 110.

Where the heating assembly 130 includes a gas reservoir 160, in fluid communication with the reactor system 140 and crucible system 150, the gas reservoir 160 may release an inert gas 362 into the gas line 245. The inert gas 362 may be released into the gas line 245 at a pressure greater than the pressure within the precursor volume 253 of the precursor housing 256 and the pressure within the reactor volume 243 of the reactor chamber 244 such that the inert gas 362 may provide a pressure flowing toward the reactor volume 243. In this manner, as precursor gas 352 flows in the gas line 245, the inert gas 362 may push the precursor gas 352 in the gas line 245 toward the reactor volume 243. This may assist in more efficiently flowing the precursor gas 352 toward the reactor volume 243. In other embodiments, where the heating assembly does not include a gas reservoir, the precursor gas may flow toward the reactor volume based on a pressure difference between the precursor volume, and the reactor volume and/or the sample chamber.

The inert gas 362 may mix with the precursor gas 352 to form a mixed gas 372 as the inert gas 362 pushes the precursor gas 352 to the reactor volume 243. This mixed gas 372 may flow into the reactor volume 243 to react with the sample 125. As the inert gas 362 in the mixed gas 372 may not chemically react with the sample 125, only the precursor gas 352 may react with the sample 125. However, in other embodiments, the gas from the gas reservoir may also react with the sample, such as where the gas reservoir releases oxygen, hydrogen, or the like. In some embodiments, a heating element (not shown) may heat up the portion of the lid 246 that the mixed gas 372 flows in to minimize the risk of precursor gas 352 loss as the mixed gas 372 travels from the precursor volume 253 to the reactor volume 243 in the gas line 245.

Once the mixed gas 372 flows into the reactor volume 243, the precursor gas 352 within the mixed gas 372 may react with the sample 125 while the charged particle beam 370 interacts with the sample 125. In some embodiments, the precursor gas 352 can be provided in measured doses by adjusting the heating element 252 to heat a desired dose portion according to temperature gradient measurements from a temperature sensor or mass data from a mass sensor. The computer system 190 can generate images of the reaction between the sample 125 and the precursor gas 352 based on the interaction between the charged particle beam 370 and the sample 125 during this reaction.

The cooling system 258 may cool down the precursor housing 256 as, or during, the imaging of the reactions between sample 125 and precursor gas 352 (e.g., during and after the heating element 252 is activated to heat up the precursor 126). Additionally, the lid 246 may be decoupled from the reactor chamber 244 to clean the reactor volume 243 and/or change the sample 125. Further, the precursor housing 256 may be decoupled from the cover 254 to clean the precursor volume 253, and/or change the precursor 126. Even further, the crucible system 150 may be decoupled from the lid 246 and changed out for another crucible system designed for a different type of precursor.

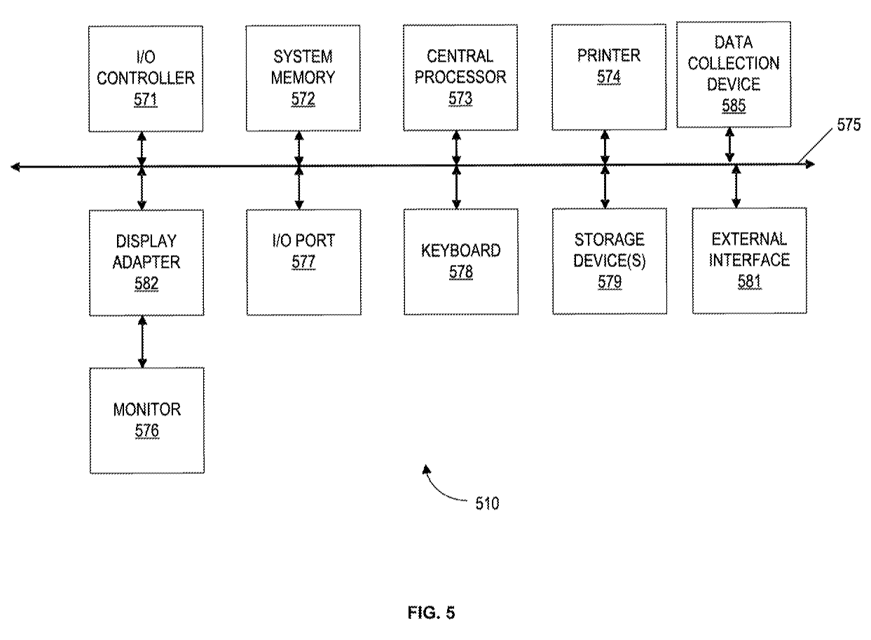

Any of the computer systems mentioned herein may utilize any suitable number of subsystems. Examples of such subsystems are shown in FIG. 5 in computer system 510, which is an example of the computer system 190. In some embodiments, a computer system includes a single computer apparatus, where the subsystems can be the components of the computer apparatus. In other embodiments, a computer system can include multiple computer apparatuses, each being a subsystem, with internal components. A computer system can include desktop and laptop computers, tablets, mobile phones and other mobile devices.

The subsystems shown in FIG. 5 are interconnected via a system bus 575. Additional subsystems such as a printer 574, keyboard 578, storage device(s) 579, monitor 576 (e.g., a display screen, such as an LED), which is coupled to display adapter 582, and others are shown. Peripherals and input/output (I/O) devices, which couple to I/O controller 571, can be connected to the computer system by any number of means known in the art such as input/output (I/O) port 577 (e.g., USB, FireWire^{®}). For example, I/O port 577 or external interface 581 (e.g., Ethernet, Wi-Fi, etc.) can be used to connect computer system 510 to a wide area network such as the Internet, a mouse input device, or a scanner. The interconnection via system bus 575 allows the central processor 573 to communicate with each subsystem and to control the execution of a plurality of instructions from system memory 572 or the storage device(s) 579 (e.g., a fixed disk, such as a hard drive, or optical disk), as well as the exchange of information between subsystems. The system memory 572 and/or the storage device(s) 579 may embody a computer readable medium. Another subsystem is a data collection device 585, such as a camera, microphone, accelerometer, and the like. Any of the data mentioned herein can be output from one component to another component and can be output to the user.

A computer system can include a plurality of the same components or subsystems, e.g., connected together by external interface 581, by an internal interface, or via removable storage devices that can be connected and removed from one component to another component. In some embodiments, computer systems, subsystem, or apparatuses can communicate over a network. In such instances, one computer can be considered a client and another computer a server, where each can be part of a same computer system. A client and a server can each include multiple systems, subsystems, or components.

Aspects of embodiments can be implemented in the form of control logic using hardware circuitry (e.g., an application specific integrated circuit or field programmable gate array) and/or using computer software stored in a memory with a generally programmable processor in a modular or integrated manner, and thus a processor can include memory storing software instructions that configure hardware circuitry, as well as an FPGA with configuration instructions or an ASIC. As used herein, a processor can include a single-core processor, multi-core processor on a same integrated chip, or multiple processing units on a single circuit board or networked, as well as dedicated hardware. Based on the disclosure and teachings provided herein, a person of ordinary skill in the art will know and appreciate other ways and/or methods to implement embodiments of the present disclosure using hardware and a combination of hardware and software.

Any of the software components or functions described in this application may be implemented as software code to be executed by a processor using any suitable computer language such as, for example, Java, C, C++, C#, Objective-C, Swift, or scripting language such as Perl or Python using, for example, conventional or object-oriented techniques. The software code may be stored as a series of instructions or commands on a computer readable medium for storage and/or transmission. A suitable non-transitory computer readable medium can include random access memory (RAM), a read only memory (ROM), a magnetic medium such as a hard-drive or a floppy disk, or an optical medium such as a compact disk (CD) or DVD (digital versatile disk) or Blu-ray disk, flash memory, and the like. The computer readable medium may be any combination of such devices. In addition, the order of operations may be re-arranged. A process can be terminated when its operations are completed, but could have additional steps not included in a figure. A process may correspond to a method, a function, a procedure, a subroutine, a subprogram, etc. When a process corresponds to a function, its termination may correspond to a return of the function to the calling function or the main function.

Such programs may also be encoded and transmitted using carrier signals adapted for transmission via wired, optical, and/or wireless networks conforming to a variety of protocols, including the Internet. As such, a computer readable medium may be created using a data signal encoded with such programs. Computer readable media encoded with the program code may be packaged with a compatible device or provided separately from other devices (e.g., via Internet download). Any such computer readable medium may reside on or within a single computer product (e.g., a hard drive, a CD, or an entire computer system), and may be present on or within different computer products within a system or network. A computer system may include a monitor, printer, or other suitable display for providing any of the results mentioned herein to a user.

Any of the methods described herein may be totally or partially performed with a computer system including one or more processors, which can be configured to perform the steps. Any operations performed with a processor (e.g., aligning, determining, comparing, computing, calculating) may be performed in real-time. The term “real-time” may refer to computing operations or processes that are completed within a certain time constraint. The time constraint may be 1 minute, 1 hour, 1 day, or 7 days. Thus, embodiments can be directed to computer systems configured to perform the steps of any of the methods described herein, potentially with different components performing a respective step or a respective group of steps. Although presented as numbered steps, steps of methods herein can be performed at a same time or at different times or in a different order. Additionally, portions of these steps may be used with portions of other steps from other methods. Also, all or portions of a step may be optional. Additionally, any of the steps of any of the methods can be performed with modules, units, circuits, or other means of a system for performing these steps.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as "bottom” or "top" and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a "bottom" surface can then be oriented "above" other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A heating assembly for use in a charged particle system comprising:
a reactor system defining a reactor chamber configured to house a sample and including a reactor heater configured to heat the sample, wherein the reactor system defines an aperture configured to receive a charged particle beam; and
a crucible system including:
a precursor housing defining a precursor volume configured to house a precursor, wherein the precursor volume is in fluid communication with the reactor chamber; and
a heating element configured to heat the precursor.

2. The heating assembly of claim 1, further comprising a gas reservoir in fluid communication with the reactor chamber and the precursor volume, wherein the gas reservoir includes an inert gas or a reaction gas.

3. The heating assembly of claim 2, wherein:
the gas reservoir includes a first pressure, the precursor volume includes a second pressure, and the reactor chamber includes a third pressure; and
the first pressure is individually greater than the second pressure and the third pressure.

4. The heating assembly of claim 1, wherein the reactor chamber includes a lid that is movable between a closed position, where the lid is disposed over the reactor chamber, and an open position, where the lid is positioned laterally away from the reactor chamber.

5. The heating assembly of claim 4, wherein the lid defines a gas line and the precursor volume is in fluid communication with the reactor chamber through the gas line.

6. The heating assembly of claim 1, wherein:
the crucible system includes a cover disposed over the precursor housing; and
the cover is removable to expose the precursor housing.

7. The heating assembly of claim 1, wherein the heating element includes a resistive heating coil.

8. A charged particle system comprising:
a beam column; and
a sample chamber that houses:
a reactor system defining a reactor chamber and including a reactor heater, wherein a beam axis is defined from the beam column into the reactor chamber, wherein the reactor system defines an aperture aligned with the beam axis; and
a crucible system including a precursor housing in fluid communication with the reactor chamber and a heating element.

9. The charged particle system of claim 8, wherein:
the sample chamber includes a first pressure, the reactor chamber includes a second pressure, and the precursor housing includes a third pressure; and
the third pressure is greater than, or substantially similar to, the second pressure and the second pressure is greater than, or substantially similar to, the first pressure.

10. The charged particle system of claim 9, wherein the first pressure includes a vacuum pressure.

11. The charged particle system of claim 8, further comprising a gas reservoir in fluid communication with the reactor chamber and the precursor housing, wherein the gas reservoir includes an inert gas or a reaction gas.

12. The charged particle system of claim 11, wherein:
the gas reservoir includes a first pressure, the precursor housing includes a second pressure, and the reactor chamber includes a third pressure; and
the first pressure is individually greater than the second pressure and the third pressure.

13. The charged particle system of claim 8, wherein the reactor chamber includes a lid that is movable between a closed position, where the lid is disposed over the reactor chamber, and an open position, where the lid is positioned laterally away from the reactor chamber.

14. The charged particle system of claim 13, wherein the lid defines the aperture.

15. The charged particle system of claim 13, wherein the lid defines a gas line and the precursor housing is in fluid communication with the reactor chamber through the gas line.

16. The charged particle system of claim 8, wherein:
the crucible system includes a cover disposed over the precursor housing; and
the cover is removable to expose the precursor housing.

17. The charged particle system of claim 8, wherein the heating element includes a resistive heating coil.

18. A method of using a charged particle system comprising:
emitting a charged particle beam through a beam column, and an aperture defined by a reactor chamber of a reactor system, onto a sample housed in the reactor chamber, wherein the reactor system is positioned in a sample chamber and includes a reactor heater;
activating the reactor heater to heat the sample; and
activating a heating element of a crucible system positioned in the sample chamber to heat a precursor housed in a precursor housing of the crucible system such that the precursor emits a precursor gas that flows into the reactor chamber, wherein the precursor housing is in fluid communication with the reactor chamber.

19. The method of claim 18, wherein the precursor housing includes a first pressure, and the method further comprises releasing a gas from a gas reservoir at a second pressure greater than the first pressure to push the precursor gas into the reactor chamber.

20. The method of claim 18, further comprising imaging a reaction between the precursor gas and the sample.
